(19) United States
(12) Patent Application Publication
(10) Pub. No.: US 2026/0295768 A1
(43) Pub. Date: Oct. 1, 2026

(54) DEVICE AND METHOD FOR PRESSING AN UPPER POLISHING CLOTH AGAINST AN UPPER POLISHING PLATE OF A MACHINE FOR SIMULTANEOUSLY POLISHING A FRONT SIDE AND A REAR SIDE OF A SEMICONDUCTOR WAFER

(71) Applicant: SILTRONIC AG, Munich (DE)

(72) Inventors: Tobias OPITZ, Freiberg (DE); Rocco HUNKE, Freiberg (DE); Jannis LIEBSCHER, Freiberg (DE); Jörg MEHNERT, Freiberg (DE)

(21) Appl. No.: 18/998,135

(22) PCT Filed: Aug. 3, 2023
(86) PCT No.: PCT/EP2023/071505

§ 371 Date: Jan. 24, 2025

(30) Foreign Application Priority Data
Aug. 12, 2022 (EP) 22190170.5

(51) Int. Cl. B24B 37/08; B24B 37/005; B24B 37/20; H10P 72/00

(52) U.S. Cl. CPC B24B 37/08; B24B 37/005; B24B 37/20; H10P 72/0428

(57) ABSTRACT

A device presses an upper polishing cloth against an upper polishing plate of a machine for simultaneously polishing a front side and a rear side of a semiconductor wafer between the upper polishing plate and a lower polishing plate. The device includes: two parallel linear rails, which are arranged at a distance above the lower polishing plate, parallel to a radius, lying in between, of the lower polishing plate; a base body to which the linear rails are fastened; two driven carriages, which are movable along the linear rails; actuators, carried by the carriages, the actuators being configured to raise and lower a roller, which is fastened to the actuators and arranged between the linear rails; and a controller configured to synchronously move the carriages to and fro between an inner pin crown and an outer pin crown of the machine and configured to synchronously move the actuators.

### CROSS REFERENCE TO RELATED APPLICATIONS

This application is a U.S. National Phase application under 35 U.S.C. § 371 of International Application No. PCT/EP 2023/071505, filed on Aug. 3, 2023, and claims benefit to European Patent Application No. EP 22190170.5, filed on Aug. 12, 2022. The International Application was published in German on Feb. 15, 2024 as WO 2024/033205 A1 under PCT Article 21 (2).

### FIELD

The present disclosure provides a device for pressing an upper polishing cloth against an upper polishing plate of a machine for simultaneously polishing a front side and a rear side of a semiconductor wafer. The present disclosure also provides a corresponding method operating the device.

### BACKGROUND

Polishing both sides of workpieces, such as semiconductor wafers, is also called double-sided polishing (DSP). The basic principles of the DSP of semiconductor wafers are described, for example, in US 2003 0 054 650 A1 and in DE 100 07 390 A1.

Generally, polishing cloths are adhesively bonded to both polishing plates of a DSP system. The polishing cloths are to be adhesively bonded without any bubbles in order to eliminate a source which negatively impacts the desired polishing result. The polishing cloth in question is also to adhere equally strongly to the polishing plate. In order to achieve the necessary adhesion, the polishing cloths can be pressed together between the polishing plates (cloth pressing). As a result of pressing, the adhesive flows and adheres better. Methods for creating an adhesive bond between the polishing cloth and the corresponding polishing plate are known from US 2007 0 087 671 A1, JP 2006 289 523 A, JP 2006 346 808 A and DE 102 39 774 A1.

Before cloth pressing, the upper polishing cloth, which is of annular form, is adhesively bonded to the upper polishing plate. Such a method is described, for example, in EP 4 000 806 A1. Bubbles in the space between the upper polishing plate and the upper polishing cloth must then be removed, because this is possible only insufficiently by means of cloth pressing alone. Such bubbles can be pushed manually by means of a doctor blade or a roller to the outside edge or inside edge of the upper polishing cloth, from where they can be pushed out of the space.

This operation is laborious and difficult, because it has to be carried out while working overhead. Although it is suggested in EP 4 000 806 A1 that the operation can also be carried out by machine, it remains open how this can be implemented.

US 2007 0 087 671 A1 recommends clamping a roller unit having radially arranged rollers between the lower and the upper polishing plates after the polishing cloths have been adhesively bonded thereto, and rotating the polishing plates in opposite directions. Because radially arranged rollers move bubbles in the space between the polishing plate and the polishing cloth mainly in the circumferential direction, they are able to remove bubbles from that space only insufficiently.

### SUMMARY

In an embodiment, the present disclosure provides a device that presses an upper polishing cloth against an upper polishing plate of a machine for simultaneously polishing a front side and a rear side of a semiconductor wafer between the upper polishing plate and a lower polishing plate. The device includes: two parallel linear rails, which are arranged at a distance above the lower polishing plate, parallel to a radius, lying in between, of the lower polishing plate; a base body to which the linear rails are fastened; two driven carriages, which are movable along the linear rails; actuators, carried by the carriages, the actuators being configured to raise and lower a roller, which is fastened to the actuators and arranged between the linear rails; and a controller configured to synchronously move the carriages to and fro between an inner pin crown and an outer pin crown of the machine and configured to synchronously move the actuators.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows features of a DSP polishing machine in a plan view of the lower polishing plate; and

FIG. 2 shows a preferred embodiment of the of the present disclosure.

### DETAILED DESCRIPTION

The present disclosure offers a more efficient solution for removing bubbles from the space between the upper polishing plate and the upper polishing cloth.

An aspect of the present disclosure provides a device for pressing an upper polishing cloth against an upper polishing plate of a machine for simultaneously polishing a front side and a rear side of a semiconductor wafer between the upper polishing plate and a lower polishing plate, comprising:
two parallel linear rails, which are arranged at a small distance above the lower polishing plate parallel to a radius, lying in between, of the lower polishing plate;
a base body to which the linear rails are fastened;
two driven carriages, which are movable along the linear rails; actuators, carried by the carriages, for raising and lowering a roller, which is fastened to the actuators and arranged between the linear rails; and
a controller for synchronously moving the carriages to and fro between an inner and an outer pin crown of the machine and for synchronously moving the actuators.

The linear rails are preferably fastened to a ring or a plate as the base body. The ring or plate rests on the lower polishing cloth and has teeth, which engage into the outer and into the inner pin crown of the machine. The linear rails can project beyond the edge of the lower polishing plate. It is, however, also possible to shorten them to a length that corresponds to the distance between the inner pin crown and the outer pin crown.

The actuators preferably work pneumatically or electrically.

An aspect of the present disclosure further provides a method for pressing an upper polishing cloth against an upper polishing plate of a machine for simultaneously polishing a front side and a rear side of a semiconductor wafer, comprising:
adhesively bonding the upper polishing cloth to the upper polishing plate; and
arranging the device, according to an embodiment of the present disclosure, above the lower polishing cloth;
arranging the upper polishing plate over the lower polishing plate at a distance from one another which allows the roller of the device to press against the upper polishing cloth; and
pressing the roller at least intermittently against the upper polishing cloth while at the same time rotating the upper polishing plate and moving the roller to and fro between the inner and the outer pin crown of the machine.

The upper polishing cloth is adhesively bonded to the upper polishing plate and brought into an intermediate state in which there are bubbles in the space between the upper polishing cloth and the upper polishing plate and the upper polishing cloth is not yet adhered evenly to the upper polishing plate. This can be effected, for example, by laying the upper polishing cloth on the lower polishing cloth, wherein the adhesive layer of the upper polishing cloth faces upwards, that is to say faces away from the lower polishing plate, and pressing the polishing plates together. It is also possible to follow the procedure described in EP 4 000 806 A1.

The device according to the present disclosure is used to remove the bubbles from the space between the upper polishing plate and the upper polishing cloth in the next step. For this purpose, the device is arranged above the lower polishing cloth and the upper polishing plate is pivoted over the lower polishing plate, so that there is a small distance between the two polishing plates. At this distance, the roller is not yet touching the upper polishing cloth, as long as the actuators have not yet raised it. However, the distance is also sufficiently small that the roller can be pressed against the upper polishing cloth by means of the actuators. The upper polishing plate is then rotated, preferably at a speed of not less than 0.1 rpm and not more than 1 rpm, particularly preferably at 0.2 rpm, and the roller is raised by means of the actuators so that it is pressed against the upper polishing cloth. The contact pressure of the roller is preferably from 1.8×10⁵ Pa to 2.0×10⁵ Pa (from 1.8 bar to 2.0 bar) and can be varied.

At the same time as the roller is being pressed against the upper polishing cloth, the roller is moved by means of the carriages along the linear rails between the inner and the outer pin crown of the polishing machine. The roller thereby drives bubbles primarily in the radial direction from the inside edge to the outside edge of the upper polishing cloth and thus out of the space between the upper polishing cloth and the upper polishing plate. The speed with which the roller is moved along the linear rails is preferably from 0.5 m/s to 1.5 m/s and can likewise be varied.

The roller is pressed at least intermittently against the upper polishing cloth while the upper polishing plate is being rotated and the roller is being moved between the inner and the outer pin crown of the machine.

According to one embodiment, the roller is moved to and fro between the inner and the outer pin crown of the polishing machine and is pressed against the upper polishing cloth while the upper polishing plate is being rotated.

According to another embodiment, the roller is moved to and fro between the inner and the outer pin crown of the polishing machine and is pressed against the upper polishing cloth only on the outward or return travel, while the upper polishing plate is being rotated.

The present disclosure will be described further with reference to drawings.

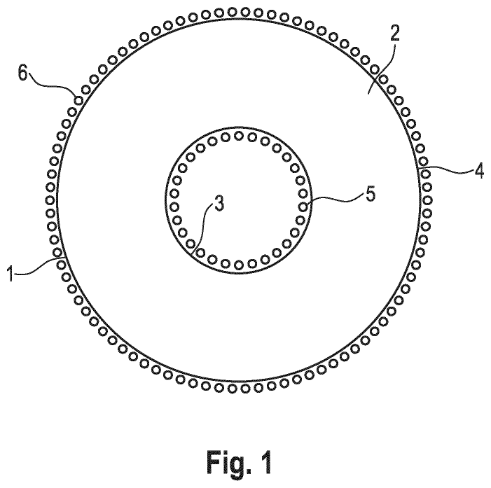

FIG. 1 shows features of a DSP polishing machine in a plan view of the lower polishing plate 1, to which an annular lower polishing cloth 2 is adhesively bonded. Parallel to the inside edge 3 and to the outside edge 4 of the lower polishing cloth 2 and of the lower polishing plate 1 there are arranged an inner pin crown 5 and an outer pin crown 6, by means of which the polishing plates 1, 8 can be rotated.

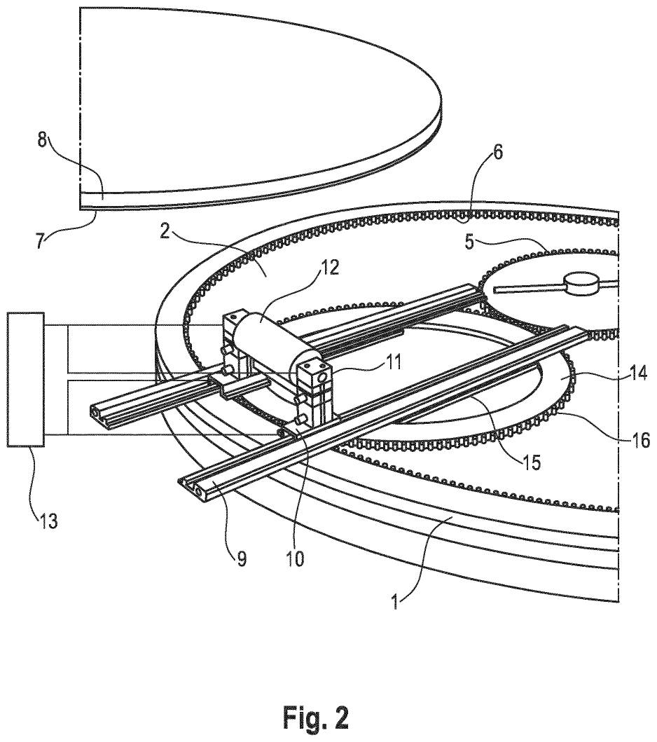

As is shown in FIG. 2, the lower polishing plate 1 is used to support the device for pressing the upper polishing cloth 7 against the upper polishing plate 8. The device comprises two parallel linear rails 9, which are arranged at a small distance above the lower polishing plate 1 parallel to a radius, lying in between, of the lower polishing plate 1. Each of the linear rails 9 serves as a guide for a carriage 10, wherein each of the carriages 10 carries an actuator 11 and a roller 12 to which actuators are fastened, so that the roller is arranged between the linear guides 9. The actuators are able to raise the roller 12 and lower it again, and the carriages 10 are able to move it along a path between the outer pin crown 6 and the inner pin crown 5. The carriages 10 and the actuators 11 each move synchronously, which is ensured by a controller 13.

According to the embodiment shown, the linear rails 9 lie on a ring 14 and on bars 15 located in the ring 14, wherein the ring 14 has external teeth 16 which engage into the outer pin crown 6 and into the inner pin crown 5 of the machine.

In order to carry out the method according to the present disclosure, the upper polishing cloth 7 is brought into an intermediate state in which there are bubbles in the space between the upper polishing cloth 7 and the upper polishing plate 8 and the upper polishing cloth 7 is not yet adhered evenly to the upper polishing plate 8.

The device for pressing the upper polishing cloth 7 against the upper polishing plate 8 is then arranged above the lower polishing cloth 2, and the upper polishing plate 8 is pushed over the lower polishing plate 1. The two polishing plates 8, 1 are at a distance from one another which allows the roller 12 of the device to press against the upper polishing cloth 7.

FIG. 2 shows the situation before the upper polishing plate 8 has been arranged over the lower polishing plate 1.

The upper polishing plate 8 is then slowly rotated and the roller 12 is moved to and fro by means of the carriages 10 between the outer pin crown 6 and the inner pin crown 5 while the actuators 11 press the roller 12 at least intermittently against the upper polishing cloth 7.

It has been shown that the advantage of the method not only consists in avoiding laborious manual work but also has an advantageous impact on the polishing result. The geometry, that is to say the flatness and plane parallelism, of polished semiconductor wafers of monocrystalline silicon was measured, as was the local geometry at the edge, and combined to form a measured value which combines the measurement results of GBIR (global flatness back ideal range) and ESFQR (edge site front least squares range). This measured value was on average almost 17.8% smaller when the upper polishing cloth had been pressed, before the polishing, against the upper polishing plate not manually but according to the present disclosure.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS USED

1 lower polishing plate
2 lower polishing cloth
3 inside edge
4 outside edge
5 inner pin crown
6 outer pin crown
7 upper polishing cloth
8 upper polishing plate
9 linear rails
10 carriage
11 actuator
12 roller
13 controller
14 ring
15 strips
16 external teeth

1. A device for pressing an upper polishing cloth against an upper polishing plate of a machine for simultaneously polishing a front side and a rear side of a semiconductor wafer between the upper polishing plate and a lower polishing plate, the device comprising:
two parallel linear rails, which are arranged at a distance above the lower polishing plate, parallel to a radius, lying in between, of the lower polishing plate;
a base body to which the linear rails are fastened;
two driven carriages, which are movable along the linear rails;
actuators, carried by the carriages, the actuators being configured to raise and lower a roller, which is fastened to the actuators and arranged between the linear rails; and
a controller configured to synchronously move the carriages to and fro between an inner pin crown and an outer pin crown of the machine and configured to synchronously move the actuators.

2. The device according to claim 1, further comprising: a ring or a plate as the base body; and bars, located in the ring, on which the linear rails are supported, wherein the ring or plate has teeth which engage into the outer pin crown and into the inner pin crown of the machine.

3. The device according to claim 1, wherein the actuators are configured to work pneumatically or electrically.

4. A method for pressing an the upper polishing cloth against the upper polishing plate of the machine for simultaneously polishing the front side and the rear side of the semiconductor wafer, the method comprising:
adhesively bonding the upper polishing cloth to the upper polishing plate; and
arranging the device according to claim 1 above the lower polishing cloth;
arranging the upper polishing plate over the lower polishing plate at a distance from one another such that the roller of the device to presses against the upper polishing cloth; and
pressing the roller at least intermittently against the upper polishing cloth while at the same time rotating the upper polishing plate and moving the roller to and fro between the inner pin crown and the outer pin crown of the machine.

5. The method according to claim 4, wherein the roller is moved to and fro between the outer pin crown and the inner pin crown of the polishing machine and at the same time is pressed against the upper polishing cloth.

6. The method according to claim 4, wherein the roller is moved to and fro between the outer pi crown and the inner pin crown of the polishing machine and is pressed against the upper polishing cloth only on the outward or return travel.
